(19) United States
(12) Patent Application Publication
(10) Pub. No.: US 2008/0160212 A1
(43) Pub. Date: Jul. 3, 2008

(54) METHOD AND APPARATUSES FOR PROVIDING ELECTRICAL CONTACT FOR PLASMA PROCESSING APPLICATIONS

(76) Inventors: Bon-Woong Koo, Andover, MA (US); Steven R. Walther, Andover, MA (US); Christopher J. Leavitt, Gloucester, MA (US); Justin Tocco, Gloucester, MA (US); Sung-Hwan Hyun, WhaSung Shi (KR); Timothy J. Miller, Ipswich, MA (US); Jay T. Scheuer, Rowley, MA (US); Atul Gupta, Beverly, MA (US); Vikram Singh, North Andover, MA (US); Deven Raj, Wenham, MA (US)

Correspondence Address: Scott Faber, Esq.;Varian Semiconductor Equipment Associates, Inc, 35 Dory Road, Gloucester, MA, 01930, US

(21) Appl. No.: 11/616,314

(22) Filed: Dec. 27, 2006

(51) Int. Cl. B28B 7/38; C23C 16/00

(52) U.S. Cl. 427/569; 118/728

(57) ABSTRACT

A method and apparatuses for providing improved electrical contact to a semiconductor wafer during plasma processing applications are disclosed. In one embodiment, an apparatus includes a wafer platen for supporting the wafer; and a plurality of electrical contact elements, each of the plurality of electrical contact elements are configured to provide a path for supplying a bias voltage from a bias power supply to the wafer on the wafer platen. The plurality of electrical contact elements are also geometrically arranged such that at least one electrical contact element contacts an inner surface region (e.g., region between a center of wafer and a distance approximately half of the radius of the wafer) and at least one electrical contact element contacts an outer annular surface region (e.g., region between an outer edge of wafer and a distance approximately half of the radius of the wafer).

### BACKGROUND

1. Technical Field

The present invention relates generally to semiconductor wafer processing, and more particularly to a method and apparatuses for providing electrical contact for plasma processing applications.

2. Related Art

Plasma processing applications, such as plasma doping (PLAD), are gaining favor as an attractive method for semiconductor device processing. PLAD, for example, offers advantages including the ability to achieve higher throughputs in semiconductor implant processing, while keeping the footprint much smaller than conventional beam-line implanters.

With PLAD applications, as the examples in FIGS. 1A and 1B show, a wafer 10 on a platen 12 is implanted with ions by applying a pulsed direct current (DC) 14 in the presence of plasma 16. During the implant process, platen, or E-chuck, 12 holds the wafer 10 down while spring-loaded pin(s) 18 provide an electrical contact to the wafer 10. The ion implantion energies are determined by DC or pulsed DC bias voltages applied to the wafer 10 at a range typically between −0.05 and −50 kV. As shown, electrodes 20 are connected through to a conductor, or plate, 22 (e.g., aluminum) and DC bias source 14. For a given plasma composition and wafer 10 substrate material, the voltage of the DC pulse 14 will determine the depth profile of the implanted species. By applying DC bias voltage to wafer 10, precise control of the incoming ion energy and implant depth profile can be achieved.

One challenge with PLAD is to provide arc-free performance. Arcing typically results when electrical contact to the wafer 10 is insufficient, and a potential difference at a gap (e.g., 26 in FIG. 1B) between the wafer 10 edge and any surrounding electrode (e.g., a shield ring 24 in FIG. 1B) builds. In order to provide a reliable arc-free performance in PLAD, robust electrical contact with the wafer is desirable. However, wafers often have various films (e.g., oxide, nitride, photo-resist, poly-silicon, etc.) on the backside of the wafer 10, which exacerbates the difficulty in obtaining optimal electrical contact on the backside of the wafer.

Further, considerable amounts of electrical current are required to flow through the wafer under PLAD processing conditions when there are high plasma density requirements due to increased throughput needs. These currents lead to voltage gradients across the wafer due to the resistivity of the bulk material, the spreading resistance of any electrical contacts, and/or the contact resistance. Voltage gradients cause a non-uniform bias across the wafer due to finite contact regions through which the current is applied. If the resistivity and/or current is sufficiently large, the voltage gradient can ultimately impact dopant junction depth, thereby affecting sheet resistance. Large voltage gradients in the region of the backside of the wafer can also lead to localized damage to the backside of the wafer in the region of electrical contact.

In view of the foregoing, there is a need in the art that addresses at least one of the aforementioned shortcomings of the related art.

### SUMMARY

A method and apparatuses for providing improved electrical contact to a semiconductor wafer during plasma processing applications are disclosed. In one embodiment, an apparatus includes a wafer platen for supporting the wafer; and a plurality of electrical contact elements, each of the plurality of electrical contact elements are configured to provide a path for supplying a bias voltage from a bias power supply to the wafer on the wafer platen. The plurality of electrical contact elements are also geometrically arranged such that at least one electrical contact element contacts an inner surface region (e.g., region between a center of wafer and a distance approximately half of the radius of the wafer) and at least one electrical contact element contacts an outer annular surface region (e.g., region between an outer edge of wafer and a distance approximately half of the radius of the wafer).

A first aspect of the disclosure is directed to an apparatus for supporting a backside of a semiconductor wafer during plasma processing application, the backside geometrically defining an inner surface region and an outer annular surface region, the apparatus comprising: a wafer platen for supporting the wafer; and a plurality of electrical contact elements, each of the plurality of electrical contact elements are configured to provide a path for supplying a bias voltage from a bias power supply to the wafer on the wafer platen, the plurality of electrical contact elements being geometrically arranged such that at least one electrical contact element contacts the inner surface region and at least one electrical contact element contacts the outer annular surface region.

A second aspect of the disclosure is directed to a method of providing electrical contact during plasma processing using a platen for contact with a backside of a semiconductor wafer, the method comprising: placing at least one electrical contact element in contact with an inner surface region of the wafer; placing at least one electrical contact element in contact with an outer annular surface region of the wafer; and plasma processing the wafer.

A third aspect of the disclosure is directed to an apparatus for supporting a backside of a semiconductor wafer during plasma processing application, the apparatus comprising: a wafer platen for supporting the wafer; and a plurality of electrical contact elements coupled to the wafer platen, wherein at least one of the plurality of electrical contact elements is located less than a distance of approximately 50 mm from an adjacent electrical contact element.

The foregoing and other features of the invention will be apparent from the following more particular description of embodiments of the disclosure.

### BRIEF DESCRIPTION OF THE DRAWINGS

The embodiments of this invention will be described in detail, with reference to the following figures, wherein like designations denote like elements, and wherein:

FIGS. 1A and 1B show cross-sectional elevation views of PLAD application environments from the related art.

FIG. 2 shows a cross-sectional elevation view of an apparatus for plasma processing application in accordance with an embodiment of the disclosure.

FIG. 3 shows a cross-sectional elevation (partial) view of an apparatus for plasma processing application in accordance with another embodiment of the disclosure.

FIG. 4 shows a cross-sectional elevation (partial) view of an apparatus for a plasma processing application in accordance with another embodiment of the disclosure.

FIGS. 5A-5F show bottom views of an arrangement of electrical contact elements and a wafer in accordance with embodiments of the disclosure.

FIGS. 6A-6B show side elevation views of an electrical contact element and a wafer in accordance with embodiments of the disclosure.

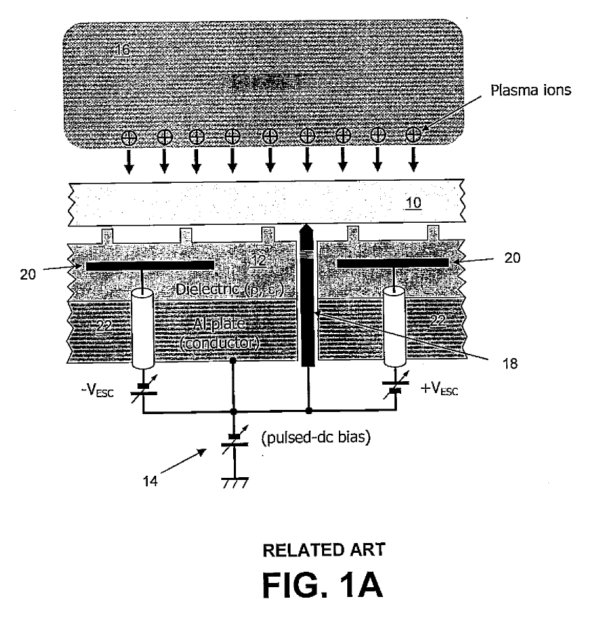

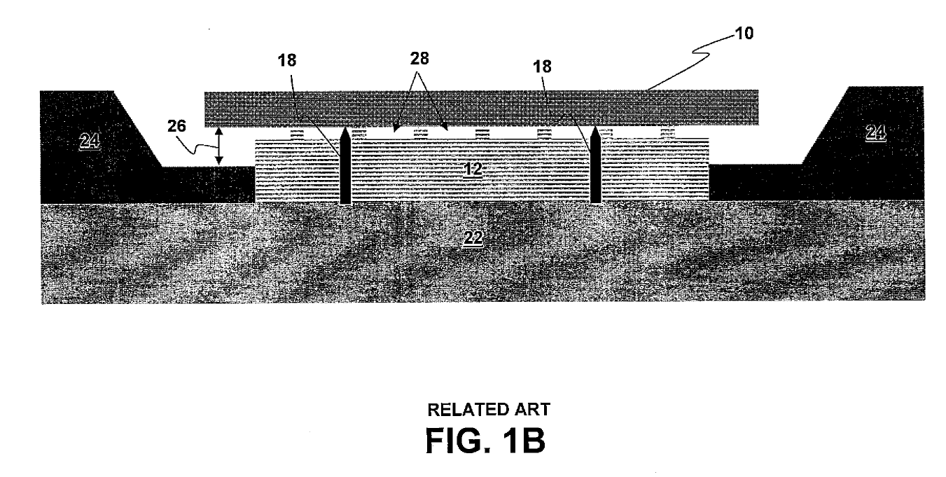

### DETAILED DESCRIPTION

A method and apparatuses for providing improved electrical contact to a semiconductor wafer during plasma processing applications are described herein.

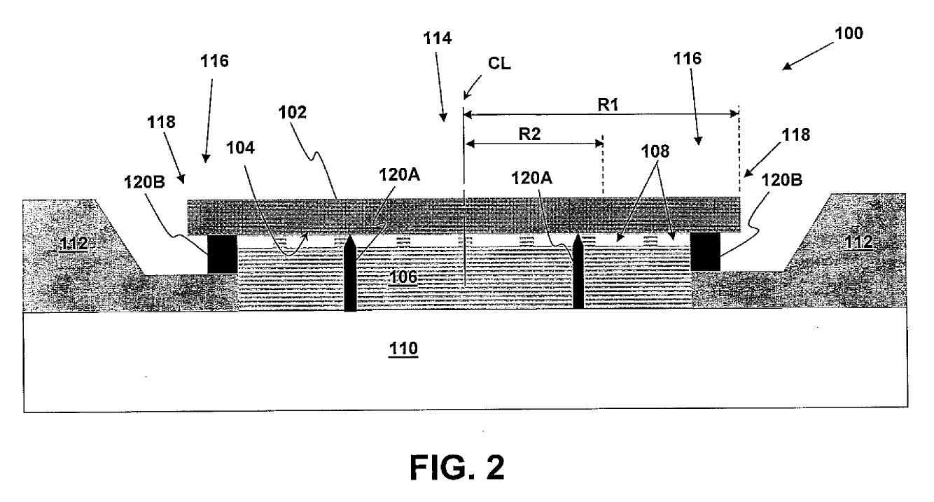

Referring to the attached drawings, FIG. 2 shows an apparatus 100 for supporting a wafer 102 during plasma processing applications (e.g., plasma doping (PLAD) application) in accordance with an embodiment of the disclosure. Wafer 102 includes a backside 104 which abuts a wafer platen 106. Optionally spaced along a top surface of wafer platen 106 is a plurality of channels 108. Further beneath platen 106 is a plate 110 and surrounding platen 106 is a shield ring 112.

In one embodiment, the geometry of wafer 102 is defined as including a first inner surface region 114 and a second outer annular surface region 116. As shown, wafer 102, generally being circular in plan, includes a geometry having a radius, R1, from a center, or centerline, (C.L.) of wafer 102. Dimension, R2, is approximately half of radius R1. In one embodiment, first portion 114 is defined as a region of wafer 102 between a center, CL, of the wafer 102 and approximately distance R2. Consequently, the second portion 116 may include a portion of wafer 102 defined as a region of wafer 102 between an outer edge 118 of wafer 102 and a distance, approximately R2.

In another embodiment, first inner surface region 114 and second outer annular surface region 116 may be defined as two portions of wafer 102 having equal areas. Thus, first inner surface region 114 may be defined as a region of wafer 102 between CL of wafer 102 and approximately distance 0.707R1. Second, outer annular surface region 116 may include a portion of wafer 102 defined as a region of wafer 102 between an outer edge 118 of wafer 102 and a distance, approximately 0.707 R1. It is understood, however, that the illustrated radial dimensions defining each region may vary, and are not considered limiting other than as recited in the attached claims. Improved attributes of wafers 102 manufactured in PLAD applications are obtained by placing a plurality of electrical contact elements 120 so that at least one electrical contact element 120A contacts first portion 114 and at least one electrical contact element 120B contacts second portion 116. In another embodiment, backside 104 of wafer 102 may be defined into other quantities of regions. For example, if N=quantity of regions that wafer 102 is apportioned, then N may exceed 2. In another embodiment, wafer 102 is defined by a plurality of outer annular surface regions 116. In this manner, electrical contact elements 120 may contact more than two outer annular surface regions 116.

Various configurations of electrical contact elements 120 and layouts thereof may be employed under aspects of the disclosure. For example, in FIG. 2, the plurality of electrical contact elements includes a first type 120A (e.g., a pin) placed in contact with first portion 114 for engagement and contact with backside 104 of wafer 102. A second type of electrical contact element 120B (e.g., an annulus) is placed in contact with second portion 116 for engagement and contact with backside 104.

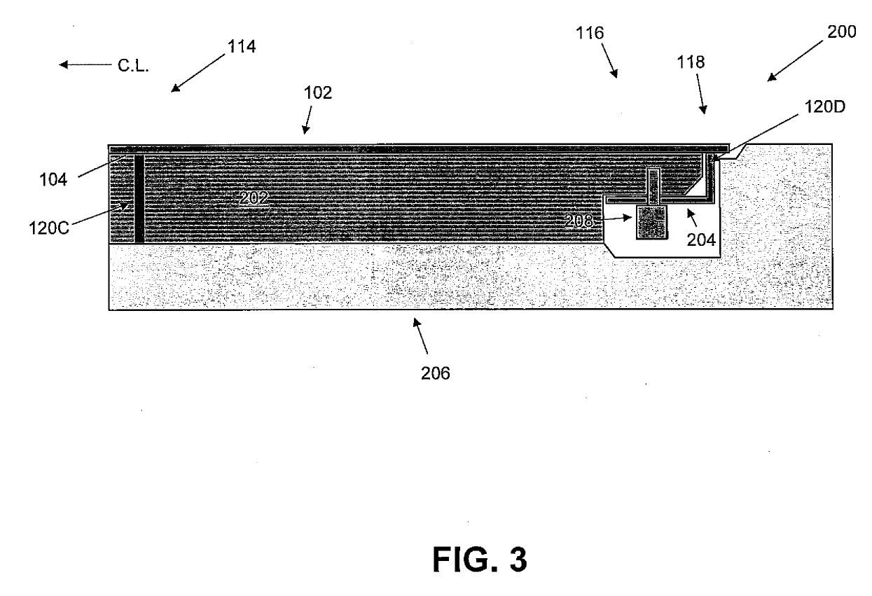

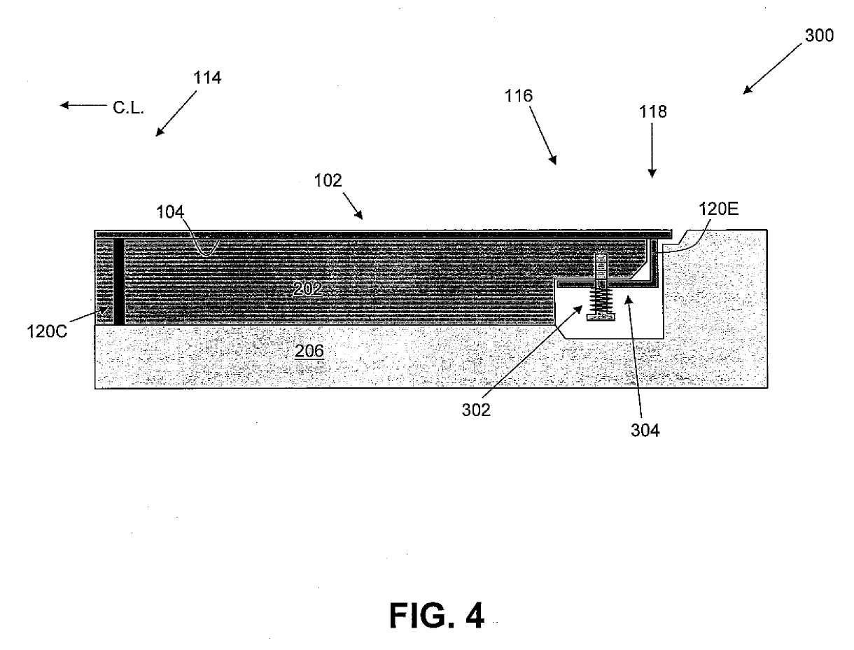

FIGS. 3 and 4 depict other embodiments of an apparatus 200, 300 for supporting a backside 104 of wafer 102. Apparatus 200, 300 include a platen (e.g., e-clamp) 202 above a pedestal (or cathode) 206. A plurality of electrical contact elements 120 (i.e., 120C, 120D in FIG. 3; and, 120C, 120E in FIG. 4) contact backside 104. Further, a Faraday cup (not shown) may also be provided to measure a dose of the ion implantation. In FIG. 3, a shield ring 204 is attached to platen 202 by an attachment 208 (e.g., plate screw, side screw, etc.). Shield ring 204 includes electrical contact element 120D (e.g., edge contact ring). By using attachment 208, edge contact ring 120D may be adjusted so as to provide suitable electrical contact with backside 104 along with electrical contact element 120C. The height of electrical contact element 120D may be precisely adjusted by attachment 208. The embodiment in FIG. 4 (i.e., apparatus 300) includes a spring 302 attached to electrical contact element 120E for biased engagement with platen 202. In this manner, suitable electrical contact is obtained between electrical contact element 120E and backside 104 by biasing electrical contact element 120E against backside 104. As a result, a pulsed DC bias may be applied to wafer 102, whereby edge arcing along and/or near an edge of wafer 102 is eliminated and/or greatly reduced.

Bench testing was conducted on apparatuses of the related art and an embodiment of an apparatus under the disclosure. Under the bench testing, the impedance for various methods of electrically contacting a wafer produced the following data: for a three (3) pinned electrical contact apparatus (see e.g., 20 in FIG. 2(a) in U.S. Pat. No. 7,126,808), when a contact voltage of 64 volts and current of 240 or 250 milli-amps is applied across a wafer, the measured resistance across the wafer is found to be in a range of 256 to 266.7 ohms. Contrastingly, when a contact voltage of 13 volts and current of 700 milli-amps is applied across a wafer 102 supported by an apparatus 100, 200, 300, according to embodiments of the disclosure, with an aluminum electrical contact element 120, as in the embodiment shown in FIG. 3, a resistance of 18.6 ohms is measured across wafer 102. Under another embodiment of the disclosure, a resistance across the wafer 102 of less than approximately 30 ohms is obtained when the wafer 102 is electrically contacted. Thus, a significant and desirable result of obtaining a low resistance across wafer 102 is achieved.

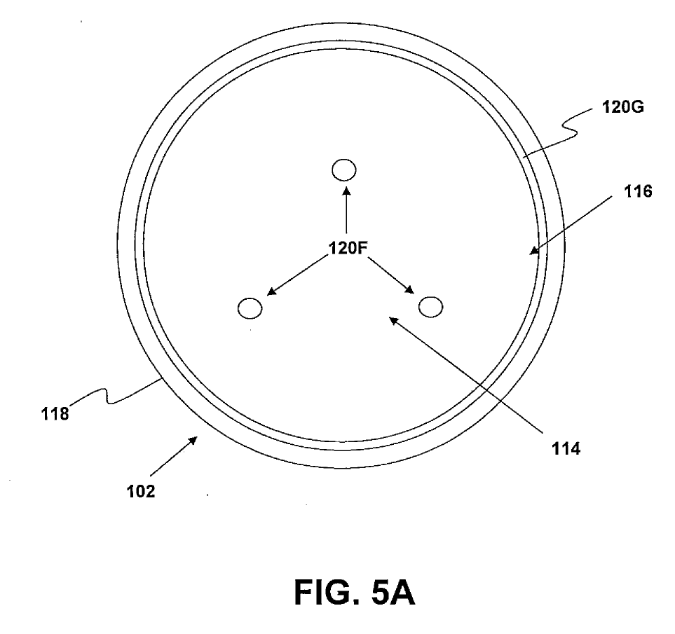

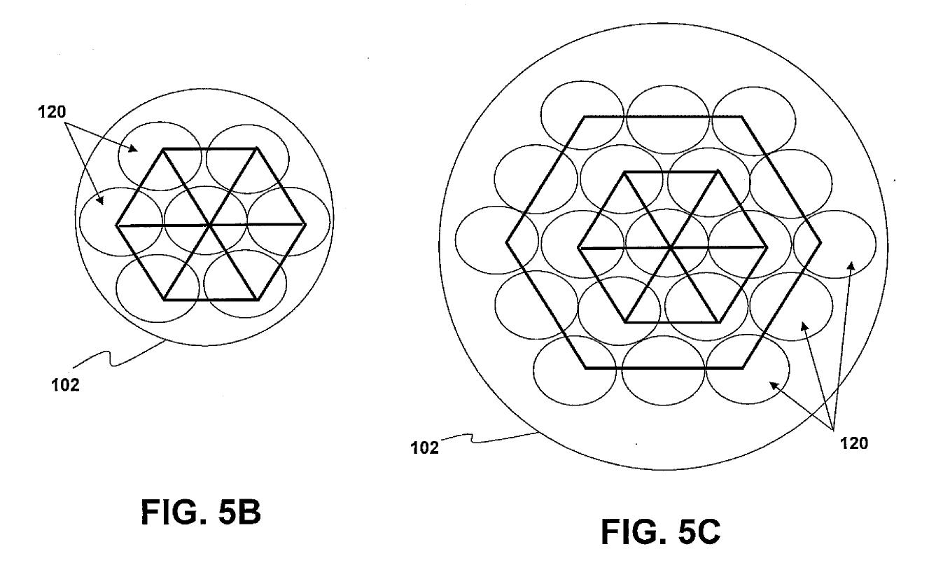

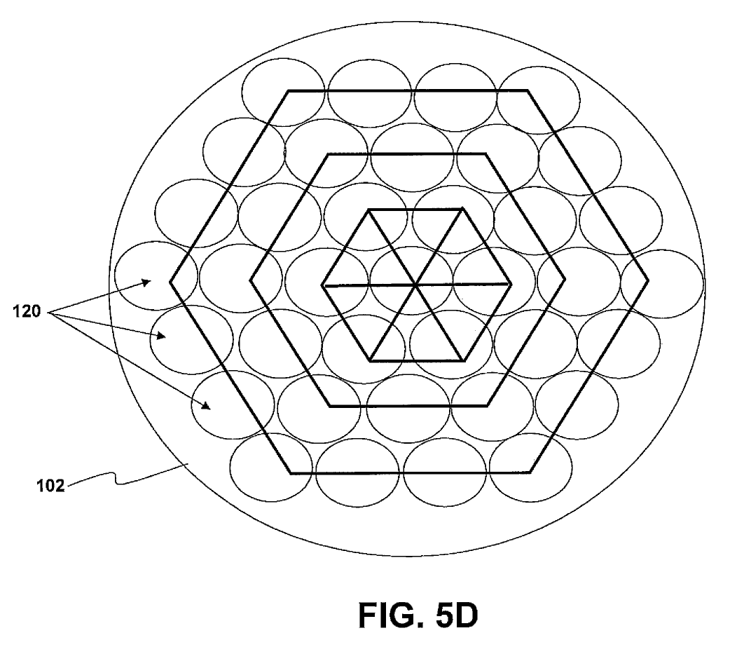

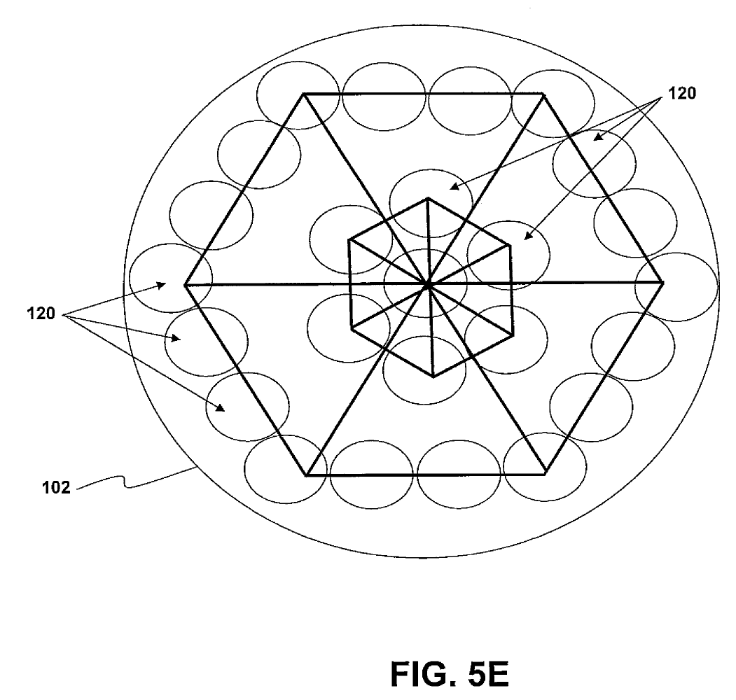

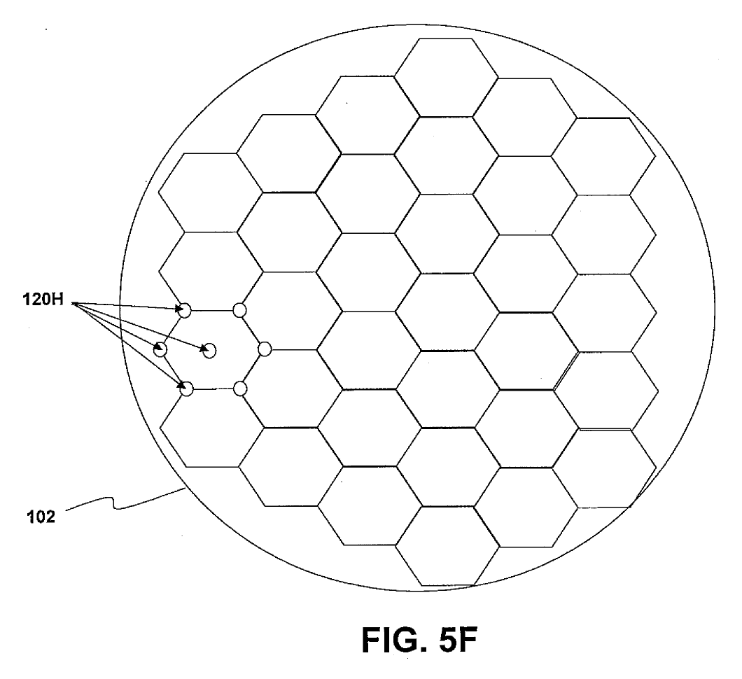

Other embodiments of providing electrical contact are shown in plan in FIGS. 5A-5F. Wafer 102 is depicted having a plurality of electrical contact elements 120 engaging and contacting with wafer 102. For example, FIG. 5A shows a first electrical contact element 120F (e.g., three contact pins), arranged in a substantially triangular geometry, and a second electrical contact element 120G (e.g., an edge ring) positioned at, or near, an outer edge 118 of wafer 102. Second electrical contact element 120G may be located a distance from outer edge 118 in a range from approximately 0 mm to approximately 20 mm. Although FIG. 5A shows a pin(s) and edge ring arrangement, other configurations achieve similar results. For example, second electrical contact element 120G may be a broken annulus, a multi-piece annulus, a plurality of pins, and/or the like. Similarly, first electrical contact element 120F may be a different quantity of pins (e.g., one, two, seven, etc.), an annulus, a broken annulus, a multi-piece annulus, and/or the like.

FIGS. 5B-5F depict other embodiments, termed herein “close-packed” configurations, for arrangement of electrical contact elements 120. In the close-packed configuration, the plurality of electrical contact elements 120 either abut (i.e., contact) each other and/or each electrical contact element 120 is located within a distance of a range from approximately 0 mm to approximately 50 mm from an adjacent electrical contact element 120 (i.e., less than approximately 50 mm). Alternatively, a total nominal contact area of plurality of electrical contact elements 120 with backside 104 (see e.g., FIG. 2) of wafer 102 may exceed approximately 50% of total area of backside 104 (i.e., ratio of total nominal contact area to backside area exceeds approximately 1:2). In another embodiment, a total nominal contact area of plurality of electrical contact elements 120 with backside 104 (see e.g., FIG. 2) of wafer 102 may exceed approximately 80% of total area of backside 104 (i.e., ratio of total nominal contact area to backside area exceeds approximately 4:5). In one embodiment, as shown in FIGS. 5B-5D, electrical contact elements 120 are arranged in a hexagonal geometry for contact with wafer 102. Various quantities of electrical contact elements 120 may be used including, for example, seven (7) (FIG. 5B); nineteen (19) (FIG. 5C); and/or thirty seven (37) (FIG. 5D). Other concentric polygon geometric arrangements may be employed for electrical contact elements 120, including a plurality of concentric polygons. For example, electrical contact elements 120 may be arranged in a triangular, square, pentagonal, or other geometry. The geometry need not be symmetrical or patterned.

In another embodiment, as shown in FIG. 5E, the electrical contact elements 120 are arranged for contact with wafer 102 in a geometry forming a plurality of concentric polygons, wherein at least two of the plurality of concentric polygons have vertices that are skewed (e.g., not in radial alignment) in relation to each other. For example, the electrical contact elements 120 may be arranged for contact with wafer 102 in concentric hexagons (e.g., two or more) such that vertices of a first hexagon pattern do not linearly align radially with vertices of a second hexagon pattern. In this manner, conductive channels (e.g., space between electrical contact elements 120) are minimized.

In another embodiment, as shown in FIG. 5F, electrical contact elements 120H (e.g., pins) are arranged in a geometry for contact with wafer 102 such that the electrical contact elements 120H are arranged at the vertices and/or a center of a polygon (e.g., hexagon). In this manner, a plurality of adjacent polygonal patterns (e.g., plurality of hexagons) of electrical contact elements 120H are arranged for contact with wafer 120. While FIG. 5F depicts a portion of a single hexagonal arrangement of electrical contact elements 120H, the plurality of electrical contact elements 120H may be arranged on any number of adjacent polygons (e.g., hexagons) for contact with wafer 102 without departing from aspects of the disclosure.

In any event, the distribution, configuration, arrangement, and/or quantity of electrical contact elements 120 to backside 104 is such so as to minimize voltage distribution across wafer 102 for a worst case resistivity (i.e., highest) wafer 102 that may be implanted by apparatus 100, 200, 300. This voltage is kept to a value such that any impact on implanted dopant junction depth will be negligible and/or zero. Further, the distribution, configuration, arrangement, and/or quantity of electrical contact elements 120 to backside 104 is selected so to minimize contact resistance and/or spreading resistance across wafer 102. These resistance values are kept at a threshold that allows no appreciable voltage drop at the maximum current during implantation.

Various materials may be used for electrical contact elements 120. Material selection may be dependent on wafer 102 substrate material (p-type or n-type) and thickness of films on wafer 102 substrate. Material selection may be optimized for either p-type or n-type material or both p-type and n-type material to be implanted. For example, suitable materials for electrical contact elements 120 may include a metal or an alloy. Further, suitable materials for electrical contact elements 120 may include Titanium, Aluminum, Tungsten, Tantalum, Cobalt, Nickel, Silicon, Silicon Carbide and/or silicide formed used the aforementioned elements.

Another aspect of the disclosure includes providing different materials on different electrical contact elements 120. For example, the plurality of electrical contact elements 120 may be defined by a first group of electrical contact elements 120 and a second group of electrical contact elements 120, wherein the first group comprises a first material and the second group comprises a second material. In this manner, the first group of electrical contact elements 120 may, for example, comprise a material type “A” suited for p-type Si substrate, while the second group of electrical contact elements 120 may, for example, comprise a material type “B” suited for n-type Si substrate, or vice versa. The first group and second group may be different, similar, and/or identical quantities of electrical contact elements 120. For example, approximately half of the total quantity of electrical contact elements 120 may be comprised of a material that is suited for p-type Si substrate, while the other half of the total quantity of electrical contact elements 120 may be comprised of a material that is suited for n-type Si substrate. Such configurations would obviate the need for two different apparatuses for processing different wafer 120 substrates (e.g., p-type Si substrate, n-type Si substrate, etc.).

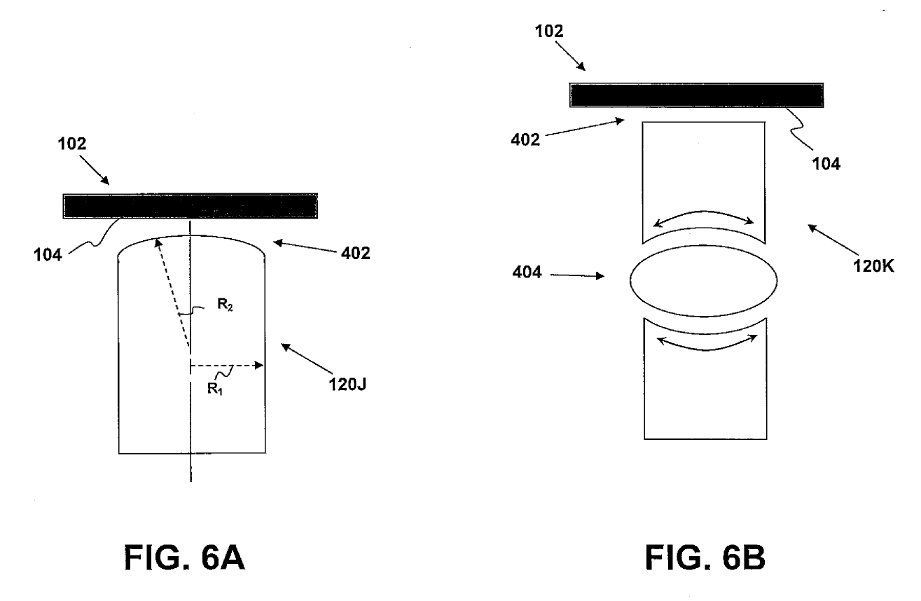

Another aspect of the disclosure includes providing an advantageous shape to an engagement end 402 of electrical contact element 120J, 120K, as shown in FIGS. 6A and 6B. The shape and surface roughness of engagement end 402 is selected to minimize both contact resistance and spreading resistance across wafer 102. By providing an electrical contact element 120J that has a relatively large radius, R₁, as shown in FIG. 6A, and/or a large radius of curvature, R₂, of engagement end 402, surface area for contacting backside 104 is maximized. For example, radius, R₁, may be in a range of approximately 0.5 mm to approximately 25 mm. Similarly, radius of curvature, R₂, may be in a range of approximately 0.5 mm to approximately 100 mm (e.g., approaching a perfectly flat surface).

As shown in FIG. 6B, another aspect of providing enhanced electrical contact to backside 104 is provided by an electrical contact element 120K that has an engagement end 402 that is substantially flat and an articulating device 404 disposed along the electrical contact element 120K. The articulating device 404 may include, for example, a mechanical pivot, hinge, and/or the like, that improves and maintains contact between electrical contact element 120K and backside 104 during wafer 102 processing. In any event, a total contact area between the plurality of electrical contact elements 120 and backside 104, under embodiments of the disclosure, may be in a range of approximately 1 mm² to approximately 400 mm².

While this disclosure has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

What is claimed is:

1. An apparatus for supporting a backside of a semiconductor wafer during plasma processing application, the backside geometrically defining an inner surface region and an outer annular surface region, the apparatus comprising:
a wafer platen for supporting the wafer; and
a plurality of electrical contact elements, each of the plurality of electrical contact elements are configured to provide a path for supplying a bias voltage from a bias source to the wafer on the wafer platen, the plurality of electrical contact elements being geometrically arranged such that at least one electrical contact element contacts the inner surface region and at least one electrical contact element contacts the outer annular surface region.

2. The apparatus of claim 1, wherein the inner surface region is defined as a region between a center of the wafer and a distance, approximately half a radius (R) of the wafer, (R/2), from the center, and the outer annular surface region is defined as a region between an outer edge of the wafer and the distance.

3. The apparatus of claim 1, wherein the inner surface region is defined as a region between a center of the wafer and a distance, approximately 0.707R, wherein R comprises a radius of the wafer, from the center, and the outer annular surface region is defined as a region between an outer edge of the wafer and the distance, approximately 0.707R.

4. The apparatus of claim 1, wherein the at least one electrical contact element contacting the outer annular surface region includes an annulus.

5. The apparatus of claim 1, wherein the plurality of electrical contact elements comprise a metal or an alloy.

6. The apparatus of claim 1, wherein the plurality of electrical contact elements comprise at least one of the following: Titanium, Aluminum, Tungsten, Tantalum, Cobalt, Nickel, Silicon, Silicon Carbide and a silicide.

7. The apparatus of claim 1, wherein at least one of the plurality of electrical contact elements comprises at least one of a cross-sectional radius in a range from approximately 0.5 mm to approximately 25 mm and an end radius in a range from approximately 0.5 mm to approximately 100 mm.

8. The apparatus of claim 1, wherein at least one of the plurality of electrical contact elements further comprise a hinge or a joint.

9. The apparatus of claim 1, wherein a total contact area of the plurality of the electrical contact elements and the backside of the wafer is in a range from approximately 1 mm² to approximately 400 mm².

10. The apparatus of claim 1, wherein the at least one electrical contact element in the inner surface region has a different shape than the at least one electrical contact element in the outer annular surface region.

11. The apparatus of claim 1, wherein the plurality of electrical contact elements provide a resistance across the wafer of less than approximately 30 ohm when the bias voltage is supplied.

12. The apparatus of claim 1, wherein the plurality of electrical contact elements geometrically form substantially a hexagon.

13. The apparatus of claim 1, wherein the plurality of electrical contact elements geometrically form a plurality of concentric polygons.

14. The apparatus of claim 13, wherein the plurality of concentric polygons comprise a first polygon having a first set of vertices and a second polygon having a second set of vertices, the first set of vertices in non-alignment radially with the second set of vertices.

15. The apparatus of claim 1, wherein the at least one electrical contact element in the outer annular surface region is located within approximately 20 mm from an outer edge of the wafer.

16. The apparatus of claim 1, wherein the outer annular surface region includes a plurality of annular surface regions.

17. The apparatus of claim 1, wherein the plurality of electrical contact elements geometrically form a plurality of adjacent polygons.

18. A method of providing electrical contact during plasma processing using a platen for contact with a backside of a semiconductor wafer, the method comprising:
placing at least one electrical contact element in contact with an inner surface region of the wafer;
placing at least one electrical contact element in contact with an outer annular surface region of the wafer; and
plasma processing the wafer.

19. The method of claim 18, wherein the backside geometrically defines an inner surface region and an outer annular surface region, the inner surface region defined as a region between a center of the wafer and a distance, approximately half of radius (R) of the wafer, (R/2), from the center and the outer annular surface region defined as a region between an outer edge of the wafer and the distance, approximately R/2.

20. The method of claim 18, wherein the backside geometrically defines an inner surface region and an outer annular surface region, the inner surface region defined as a region between a center of the wafer and a distance, approximately 0.707R, wherein R comprises approximately a radius of the wafer, from the center and the outer annular surface region defined as a region between an outer edge of the wafer and the distance, approximately 0.707R.

21. The method of claim 18, wherein the at least one electrical contact element contacting the outer annular surface region includes an annulus.

22. The method of claim 18, wherein the plurality of electrical contact elements comprise a metal or an alloy.

23. The method of claim 18, wherein the plurality of electrical contact elements comprise at least one of the following: Titanium, Aluminum, Tungsten, Tantalum, Cobalt, Nickel, Silicon, Silicon Carbide and a silicide.

24. The method of claim 18, wherein at least one of the plurality of electrical contact elements comprises at least one of a cross-sectional radius in a range from approximately 0.5 mm to approximately 25 mm and an end radius in a range from approximately 0.5 mm to approximately 100 mm.

25. The method of claim 18, wherein at least one of the plurality of electrical contact elements further comprise a hinge or a joint.

26. The method of claim 18, wherein a total contact area of the plurality of the electrical contact elements and the backside of the wafer is in a range from approximately 1 mm² to approximately 400 mm².

27. The method of claim 18, wherein the at least one electrical contact element in the inner surface region is a different shape than the at least one electrical contact element in the outer annular surface region.

28. The method of claim 18, further comprising:
electrically contacting the wafer; and
obtaining a resistance across the wafer of less than approximately 30 ohms.

29. The method of claim 18, wherein the plurality of electrical contact elements geometrically form substantially a hexagon.

30. The method of claim 18, wherein the plurality of electrical contact elements geometrically form a plurality of concentric polygons.

31. The method of claim 30, wherein the plurality of concentric polygons comprise a first polygon having a first set of vertices and a second polygon having a second set of vertices, the first set of vertices in non-alignment radially with the second set of vertices.

32. The method of claim 18, wherein the at least one electrical contact element in the outer annular surface region is located within approximately 20 mm from an outer edge of the wafer.

33. The method of claim 18, wherein the plurality of electrical contact elements geometrically form a plurality of adjacent polygons.

34. An apparatus for supporting a backside of a semiconductor wafer during plasma processing application, the apparatus comprising:
a wafer platen for supporting the wafer; and
a plurality of electrical contact elements coupled to the wafer platen, wherein at least one of the plurality of electrical contact elements is located less than a distance of approximately 50 mm from an adjacent electrical contact element.

35. The apparatus of claim 34, wherein a ratio of a total nominal contact area of the plurality of electrical contact elements to a total area of the backside of the wafer is at least approximately 1:2.

36. The apparatus of claim 35, wherein the ratio is at least approximately 4:5.

37. The apparatus of claim 34, wherein the at least one of the plurality of electrical contact elements is contacting an adjacent electrical contact element.

38. The apparatus of claim 34, wherein the plurality of electrical contact elements geometrically form substantially a polygon.
